(19) United States
(12) Patent Application Publication
(10) Pub. No.: US 2014/0042568 A1
(43) Pub. Date: Feb. 13, 2014

(54) NONVOLATILE SEMICONDUCTOR MEMORY DEVICE

(71) Applicant: KABUSHIKI KAISHA TOSHIBA, Tokyo (JP)

(72) Inventor: Koji YAMAKAWA, Tokyo (JP)

(73) Assignee: Kabushiki Kaisha Toshiba, Tokyo (JP)

(21) Appl. No.: 13/789,105

(22) Filed: Mar. 7, 2013

(30) Foreign Application Priority Data
Aug. 10, 2012 (JP) 2012-178069

(51) Int. Cl. H01L 43/02; H01L 43/12

(52) U.S. Cl. CPC H01L 43/02; H01L 43/12
USPC 257/421; 438/3

(57) ABSTRACT

A nonvolatile semiconductor memory device is provided with an MRAM chip including a magnetoresistive effect element having a reference layer whose magnetizing direction is set, a memory layer whose magnetizing direction is variable, and a nonmagnetic layer between these layers, and an enclosure having a thermal insulation area that covers part or the whole of the MRAM chip and prevents thermal fluctuation of the magnetization of the reference layer or memory layer.

### CROSS-REFERENCE TO RELATED APPLICATION

This application is based upon and claims the benefit of priority from Japanese Patent Application No. 2012-178069, filed Aug. 10, 2012; the entire contents of which are incorporated herein by reference.

### FIELD

Embodiments described herein relate to a nonvolatile semiconductor memory device.

### BACKGROUND

One methodology to improve the reliability of magnetic random access memories, is to reduce the fluctuation in the magnetizing direction of a memory layer caused by increased temperature. To this end, the coercive force or energy needed to switch the memory layer may be increased, and thereby the thermal stability of a magnetoresistive effect element may be improved. However, when the coercive force of the memory layer is increased, the resulting improvement of the thermal stability of the memory layer causes an increase of the magnetization reversal energy of the memory layer. In addition, if the magnetization reversal energy of the memory layer is increased, a large write current is required, thus increasing the power consumption of a device using the memory.

Therefore, in magnetic random access memories, the reduction of the write current and the improvement of the thermal stability have a trade-off relationship, and it is very difficult to simultaneously improve both.

### DESCRIPTION OF THE DRAWINGS

FIG. 1 is a conceptual diagram showing the nonvolatile semiconductor memory device.

FIG. 2 is a cross section showing the structure of a first embodiment of the nonvolatile semiconductor memory device.

FIG. 3 is a cross section showing the structure of a second embodiment of the nonvolatile semiconductor memory device . . . .

FIG. 4 is a cross section showing the structure of a third embodiment of the nonvolatile semiconductor memory device . . . .

FIG. 5 is a cross section showing the structure of a fourth embodiment of the nonvolatile semiconductor memory device . . . .

FIG. 6 is a cross section showing the manufacturing method of the first embodiment of the nonvolatile semiconductor memory device . . . .

FIG. 7 is a cross section showing the manufacturing method of the first embodiment of the nonvolatile semiconductor memory device . . . .

FIG. 8 is a cross section showing the manufacturing method of the first embodiment of the nonvolatile semiconductor memory device . . . .

FIG. 9 is a cross section showing the manufacturing method of the first embodiment of the nonvolatile semiconductor memory device . . . .

FIG. 10 is a cross section showing the manufacturing method of the first embodiment of the nonvolatile semiconductor memory device . . . .

FIG. 11 is a cross section showing the manufacturing method of the second embodiment of the nonvolatile semiconductor memory device . . . .

FIG. 12 is a cross section showing the manufacturing method of the second embodiment of the nonvolatile semiconductor memory device . . . .

FIG. 13 is a cross section showing the manufacturing method of the second embodiment of the nonvolatile semiconductor memory device . . . .

FIG. 14 is a cross section showing the manufacturing method of the second embodiment of the nonvolatile semiconductor memory device . . . .

FIG. 15 is a cross section showing the manufacturing method of the second embodiment of the nonvolatile semiconductor memory device . . . .

FIG. 16 is a cross section showing the manufacturing method of the third embodiment of the nonvolatile semiconductor memory device . . . .

FIG. 17 is a cross section showing the manufacturing method of the third embodiment of the nonvolatile semiconductor memory device . . . .

FIG. 18 is a cross section showing the manufacturing method of the third embodiment of the nonvolatile semiconductor memory device . . . .

FIG. 19 is a cross section showing the manufacturing method of the third embodiment of the nonvolatile semiconductor memory device . . . .

FIG. 20 is a cross section showing the manufacturing method of the fourth embodiment of the nonvolatile semiconductor memory device . . . .

FIG. 21 is a cross section showing the manufacturing method of the fourth embodiment of the nonvolatile semiconductor memory device . . . .

FIG. 22 is a cross section showing the manufacturing method of the fourth embodiment of the nonvolatile semiconductor memory device . . . .

FIG. 23 is a cross section showing the manufacturing method of the fourth embodiment of the nonvolatile semiconductor memory device . . . .

FIG. 24 is a circuit diagram showing a structural example of a magnetic random access memory.

FIG. 25 is a cross section showing an example of a memory cell.

FIG. 26 is a cross section showing an example of a magnetoresistive effect element.

FIG. 27 is a cross section showing an example of a magnetoresistive effect element.

### DETAILED DESCRIPTION

An embodiment of the present disclosure proposes a technique for realizing the reduction of a write current and an improvement of thermal stability.

In general, an embodiment, will be explained with reference to the drawings.

According to an embodiment, a nonvolatile semiconductor memory device is provided with an MRAM chip including a magnetoresistive effect element having a reference layer whose magnetizing direction is set, a memory layer whose magnetizing direction is variable, and a nonmagnetic layer between these layers; and an enclosure having a thermal insulation area that covers part or the whole of the MRAM chip and prevents thermal fluctuation of the magnetization of the memory layer.

According to an embodiment, the method for mounting the nonvolatile semiconductor memory device includes a process that mounts the enclosure having the MRAM chip, in which the magnetizing direction of the reference layer or both the reference layer and the memory layer are set to a predetermined direction, on a wiring substrate; and a process that places the wiring substrate (circuit board), on which the enclosure has been mounted, in a reflow furnace to fix the enclosure onto the wiring substrate.

### (Basic Concept)

In a magnetic random access memory (MRAM), thermal fluctuation in the magnetization direction of a reference layer and a memory layer can lead to erratic reading and writing of data or failure of the device. It is understood that one of the causes of these issues is exposure to heat and high temperatures during the mounting and packaging processes for a MRAM chip. For example, in case the MRAM chip is mounted on a wiring substrate, a temperature of 250° C. or higher is applied to the MRAM chip to reflow solder to enable connecting a package having an MRAM chip to a wiring substrate.

When a magnetoresistive effect element is subjected to this high-temperature environment, various problems occur.

For example, spin-transfer-torque magnetic random access memories utilizing the magnetoresistive effect element with a vertical magnetizing material, have been adopted. To improve the thermal stability of the reference layer and the memory layer, the size of the magnetoresistive effect element has been increased. This is contradictory to the miniaturization or device size shrink of magnetoresistive effect devices having a vertical magnetizing material employing spin-transfer-torque writing.

In addition, if the thermal stability of the memory layer is improved, since the magnetization reversal energy is also increased, a large write current, that is, a large driving transistor (FET) is required.

One objective of the following embodiments is to reduce the thermal fluctuation of the memory layer of the magnetoresistive effect element during the packaging process, including the attachment of a packaged MRAM device to a wiring substrate or circuit board, wherein the packaging process and package for the MRAM chip is modified to reduce the temperature and heat level experienced by the MRAM chip during packaging.

Therefore, if thermal fluctuation and load issues can be reduced during the packaging, the size of the magnetoresistive effect chip, and the size of the element itself, can be reduced, the magnetization reversal energy (coercive force) can be lowered, and a write current can be decreased.

FIG. 1 is a conceptual diagram showing the cross section of the nonvolatile semiconductor memory device having an MRAM chip.

An MRAM chip 11 is provided with a magnetoresistive effect element having a reference layer whose magnetizing direction is set, a memory layer whose magnetizing direction is variable, and a nonmagnetic layer between these layers. In addition, an enclosure 12 covers the MRAM chip 11. In the figure, the enclosure 12 is depicted with an image that covers the whole of the MRAM chip 11, however the enclosure 12 may cover part of the MRAM chip 11.

In addition, the enclosure 12 has a thermal insulation area 13 for preventing the thermal fluctuation of magnetization of the memory layer of the magnetoresistive effect element in the MRAM chip 11.

The thermal insulation area 13 covers part or the whole of the MRAM chip 11. In the figure, the thermal insulation area 13 is depicted with an image that covers the upper surface and the lower surface of the MRAM chip 11. However the thermal insulation area is not limited to this configuration. For example, only one of the upper surfaces and the lower surface of the MRAM chip 11 may be covered, or the side surface of the MRAM chip 11 may also be covered.

Moreover, in the figure, part of the enclosure 12 is depicted as the thermal insulation area 13, however the enclosure 12 itself, that is, the whole of the enclosure 12 may be the thermal insulation area 13.

According to this nonvolatile semiconductor memory device, since the thermal insulation area 13 is installed in the enclosure 12, the thermal fluctuation of the magnetoresistive effect element in the mounting process can be reduced by the thermal insulation area 13.

Therefore, in magnetic random access memories utilizing the magnetoresistive effect element with a vertical magnetizing material and the spin-transfer-torque write, the thermal fluctuation problem is ameliorated. The size of the magnetoresistive effect element can be reduced, the magnetization reversal energy (coercive force) can be lowered, and a write current can be decreased.

Therefore, with the reduction of the write current and the improvement of the thermal stability based on the basic concept in which the thermal fluctuation is reduced by the approach from the packaging, these two tasks, which has been a conventional trade-off relation, can be simultaneously solved.

In addition, according to this concept, in the mounting process for fixing the enclosure 12 onto a wiring substrate, even if the wiring substrate on which the enclosure 12 has been mounted is arranged in a reflow furnace, the magnetizing direction of the memory layer of the magnetoresistive effect element in the MRAM chip 11 is not changed by the thermal fluctuation.

Therefore, when the MRAM chip is manufactured, although the magnetizing direction of the reference layer and the memory layer of the magnetoresistive effect element in the MRAM chip 11 is set (initialization), a negative influence on the subsequent write operation due to the disturbance of this setting state in the subsequent processes, for example, a mounting process can also be reduced.

Moreover, since the thermal fluctuation during the mounting process is reduced, an application for writing program data (ROM data) into the magnetoresistive effect element in the MRAM chip 11 is also possible when the MRAM chip is manufactured.

Here, it is desirable for the thermal insulation area 13 to have a thermal conductivity of 0.3 W/mK or lower, and it is more desirable for the thermal insulation area to have a thermal conductivity of 0.1 W/mK or lower.

Conventional packaging materials (for example, epoxy resin) have a thermal conductivity value of about 0.35 W/mK, enabling excessive heat transfer into the MRAM chip causing thermal fluctuation of the memory layer in the high-temperature environment (250° C. or higher) of the mounting process.

For example, when a magnetic random access memory utilizing the magnetoresistive effect element with a vertical magnetizing material and the spin-transfer-torque write is packaged using the thermal insulation 13, it was confirmed that the thermal conductivity of the thermal insulation area 13 required for preventing the magnetization reversal of the memory layer due to the thermal fluctuation is 0.3 W/mK or lower. However, in this experiment, four of 250° C., 300° C., 350° C., and 400° C. are adopted as parameters in the high-temperature environment, and four of 30 nm, 40 nm, 50 nm, and 60 nm are adopted as parameters in the size (in-plane size) of the magnetoresistive effect element.

Thus, the memory device, when packaged, is heated from an ambient of about less than 30° C. to a soldering temperature of at least 250° C., and then cooled back to ambient temperature. In addition, as materials for realizing the thermal conductivity of 0.3 W/mK or lower, low-density materials, resins with low thermal conductivity, inorganic materials with low thermal conductivity, gases with low thermal conductivity, liquids with low thermal conductivity, etc., can be selected.

The low-density materials, for example, include insulating foam material, porous insulating material, insulating material with micro-pores, insulating material with a hollow structure etc.

As examples of a low-density material, urethane foam (about 0.021 W/mK), raw cotton (about 0.029 W/mK), foam plastic (about 0.03 W/mK), polystyrene (about 0.03 W/mK), polyurethane foam (about 0.03 W/mK), etc., can be mentioned.

As examples of a resin with low thermal conductivity, PTFE (about 0.25 W/mK), nylon (about 0.25 W/mK), phenol resin (about 0.29 W/mK), rubber (about 0.13 W/mK), etc., can be mentioned.

As examples of an inorganic material with low thermal conductivity, glass wool (about 0.04 W/mK), glass fiber (about 0.04 W/mK), calcium silicate (about 0.05 W/mK), etc., can be mentioned.

As examples of a gas with low thermal conductivity, inert gases (inert gas) such as He, Ne, Ar, Kr, Xe, and Rn, air, etc., can be mentioned. For example, the thermal conductivity of Ar gas is about 0.016 W/mK, the thermal conductivity of Xe gas is about 0.04 W/mK, the thermal conductivity of Kr gas is about 0.0088 W/mK, and the thermal conductivity of air is about 0.024 W/mK.

The pressure of these gases is preferably atmospheric pressure. However, the pressure of a gas constituting the thermal insulation area 13 can be lower than atmospheric pressure so long as a the integrity of the enclosure is not negatively affected.

As examples of a liquid with low thermal conductivity, silicone oil (about 0.1 W/mK), PVA (about 0.21 W/mK), etc., can be mentioned.

Here, one of these material examples may be adopted as a material constituting the thermal insulation area 13. At least two of these material examples may be combined and adopted as a material constituting the thermal insulation area 13.

In one example, the nonvolatile semiconductor memory device, for example, has a package structure in which the whole of the MRAM chip 11 is covered with a resin with low thermal conductivity as a mold resin.

In a further example, the nonvolatile semiconductor memory device, for example, has a package structure in which the lower surface of the MRAM chip 11 is covered with low-density material, resin with low thermal conductivity, inorganic material with low thermal conductivity, etc., and the upper surface of the MRAM chip 11 is covered with a gas with low thermal conductivity.

Moreover, in this further example when the nonvolatile semiconductor memory device is provided with the MRAM chip 11 through a flip-chip connection, the structure may be adopted, or the lower surface (the surface at a bump) of the MRAM chip 11 may also be covered with a gas with low thermal conductivity. In this case, the upper surface of the MRAM chip 11 maybe covered with low-density material, resin with low thermal conductivity, an inorganic material with low thermal conductivity, etc., or may also be covered with a gas with low thermal conductivity.

In any of these cases, the thermal insulation area 13 is preferably a material that does not mechanically damage electrodes or wirings of the MRAM chip 11, that is, does not cause high resistance, or disconnection of the electrodes or wiring from the chip. Especially in a structure in which electrodes or wirings of the MRAM chip 11 are easily damaged, it is very desirable to cover the thermal insulation area 13 with a gas with low thermal conductivity.

### EMBODIMENTS

Next, several embodiments in which the technical concept is embodied will be explained.

### First Embodiment

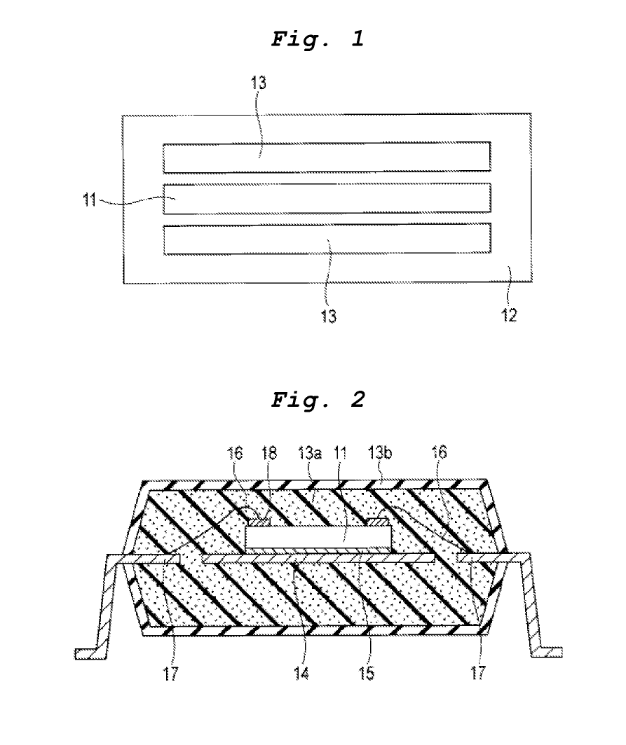

FIG. 2 shows the first embodiment of the nonvolatile semiconductor memory device.

This example relates to a molded package.

The MRAM chip 11 is fixed onto a die pad 14 of a lead frame by a conductive paste 15. Bonding wires 16 electrically connect inner leads 17 of the lead frame and external electrodes (pads) 18 of the MRAM chip 11.

The MRAM chip 11 is surrounded with an insulating material 13a as the thermal insulation area 13 of FIG. 1. The insulating material 13a is, for example, composed of a resin with low thermal conductivity. However, the insulating material 13a may be a low-density material, inorganic materials with low thermally conductivity, etc.

In addition, the insulating material 13a is covered with a molding material 13b. As the molding material 13b, for example, an epoxy resin, which is often used in a molded package, may be used.

The molding material 13b is used to make this device undifferentiated from the conventional nonvolatile semiconductor memory device (package) and to prevent the admixture of water, etc., from the outside. Therefore, even if the insulating material 13a is exposed, when there is no problem in terms of appearance or reliability, the molding material 13b can also be omitted.

Therefore, according to the first embodiment, the whole of the MRAM chip is covered with the insulating material 13a as the thermal insulation area 13 of FIG. 1. Therefore, in this case, a nonvolatile semiconductor memory device is placed in a high-temperature environment during the mounting process, and the reversal of the magnetization direction of the reference layer or memory layer of the magnetoresistive effect element due to the thermal fluctuation can be reduced.

### Second Embodiment

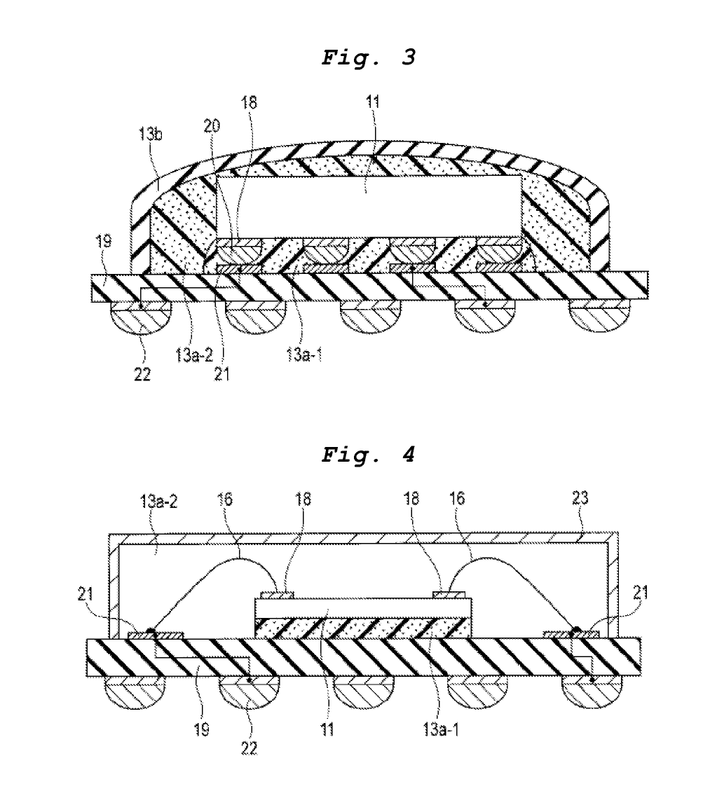

FIG. 3 shows the second embodiment of the nonvolatile semiconductor memory device.

This example also relates to a molded package.

The MRAM chip 11 is fixed onto a first surface of a wiring substrate (for example, epoxy substrate) 19 by a flip-chip connection. For example, electrodes (solid bumps) 20 are connected with the external terminals (pads) 18 of the MRAM chip 11. In addition, the electrodes 20 of the MRAM chip 11 are connected to conducting wires 21 on the wiring substrate 19.

Here, an anisotropic conductive film may be arranged between the electrode 20 of the MRAM chip 11 and the conducting wire 21 of the wiring substrate 19.

The lower surface (the surface at the electrode 20) of the MRAM chip 11 is covered with an insulating material 13a-1. In other words, the insulating material 13a-1 as the thermal insulation area 13 of FIG. 1 between the MRAM chip 11 and the wiring substrate 19. The insulating material 13a-1, for example, is composed of the resin with low thermal conductivity. However, the insulating material 13a-1 may be low-density materials, inorganic materials with low thermal conductivity, etc.

In addition, the upper surface and the side surface of the MRAM chip are covered with an insulating material 13a-2 which may be the same as that located in the thermal insulation area 13 of FIG. 1. Similar to the insulating material 13a-1, the insulating material 13a-2, for example, is composed of resins with low thermal conductivity, low-density materials, inorganic materials with low thermal conductivity, etc.

Here, the insulating materials 13a-1 and 13a-2 may be the same material or a different material.

Moreover, the insulating material 13a-2 is covered with the molding material 13b. As the molding material 13b, an epoxy resin, which is often used in molded packages, maybe adapted.

The molding material 13b is used to make this device is outwardly undifferentiated from a conventional nonvolatile semiconductor memory device (package) or to prevent the admixture of water, etc., from the outside. Therefore, even if the insulating material 13a-2 is exposed, when there is no problem in terms of appearance or reliability, the molding material 13b can also be omitted.

On a second surface of the wiring substrate 19, external terminals 22 of the package are arranged. The external terminals 22 of the package are connected to the electrodes 20 of the MRAM chip 11 via the conducting wires in the wiring substrate 19. In this example, the external terminals 22 of the package are depicted with an image of conductive bumps (solder bumps), however instead of the conductive bumps, conductive pins (metal pillars) may also be adapted.

Therefore, according to the second embodiment, the whole of the MRAM chip is covered with the insulating materials 13a-1 and 13a-2 as the thermal insulation area 13 of FIG. 1. Therefore, in case this nonvolatile semiconductor memory device is placed in a high-temperature environment during the mounting process, the magnetization direction reversal of the reference layer or memory layer of the magnetoresistive effect element due to the thermal fluctuation can be suppressed.

Here, in case an anisotropic conductive film is arranged between the electrode 20 of the MRAM chip 11 and the conducting wire 21 of the wiring substrate 19, an Anisotropic Conductive Film (ACF) or Anisotropic Conductive Paste) (ACP) is used as the anisotropic conductive film. The ACF or ACP is composed of a material containing conductive particles in an adhesive material called a binder. In this case, as in the binder, a material with a thermal conductivity of 0.3 W/mK or lower is more preferably used.

### Third Embodiment

FIG. 4 shows the third embodiment of the nonvolatile semiconductor memory device.

This example relates to a metal cap type package. The MRAM chip 11 is arranged on the first surface of the wiring substrate (for example, epoxy substrate) 19. In addition, the insulating material 13a-1 as the thermal insulation area 13 of FIG. 1 is arranged between the MRAM chip 11 and the wiring substrate 19. The insulating material 13a-1 is preferably a sheet form. The insulating material 13a-1, is composed of low-density materials, resins with low thermal conductivity, inorganic materials with low thermal conductivity, etc.

The insulating material 13a-1 may have a function as an anisotropic conductive film or a function as a conductive paste.

The bonding wire 16 electrically connects the conducting wires 21 on the first surface of the wiring substrate 19 and the external electrodes (pads) 18 of the MRAM chip 11.

A metal cap 23 is mounted on the wiring substrate 19 and covers the upper surface and the side surface of the MRAM chip 11. The area enclosed with the wiring substrate 19 and the metal cap 23 functions as the thermal insulation area 13 of FIG. 1. In this area, the insulating material 13a-2 is filled. The insulating material 13a-2 is composed of gases with low thermal conductivity or liquids with low thermal conductivity, etc.

On the second surface of the wiring substrate 19, the external terminals 22 of the package are arranged. The external terminals 22 of the package are connected to the external terminals 18 of the MRAM chip 11 via the conducting wires 21 and the bonding wires 16 in the wiring substrate 19. In this example, the external terminals 22 of the package are depicted with an image as conductive bumps (solder bumps), however instead of the conductive bumps, conductive pins (metal pillars) may also be adapted.

Here, in this example, part or the whole of the metal cap 23 may be covered with a molding material such as epoxy resin.

Therefore, according to the third embodiment, the whole of the MRAM chip is covered with the insulating materials 13a-1 and 13a-2 as the thermal insulation area 13 of FIG. 1. Therefore, in case this nonvolatile semiconductor memory device is placed in a high-temperature environment during the mounting and packaging process, the magnetization direction reversal of the reference layer or memory layer of the magnetoresistive effect element due to the thermal fluctuation may be reduced.

### Fourth Embodiment

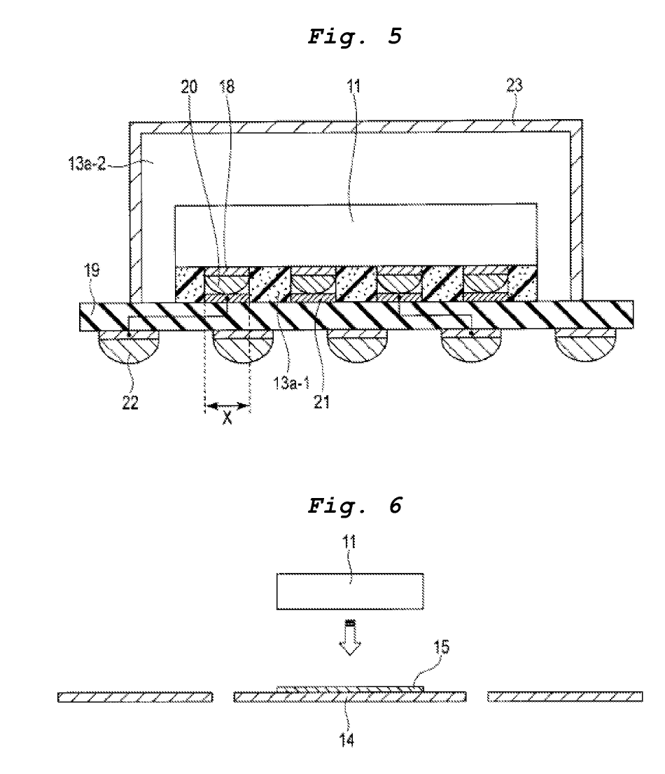

FIG. 5 shows the fourth embodiment of the nonvolatile semiconductor memory device.

This example relates to a metal cap type package.

The MRAM chip 11 is fixed onto the first surface of the wiring substrate (for example, epoxy substrate) 19 by a flip-chip connection. The electrodes (solid bumps) 20 are connected with the external terminals (pads) 18 of the MRAM chip 11. In addition, the electrodes 20 of the MRAM chip 11 are connected to the conducting wires 21 on the wiring substrate 19.

The lower surface (the surface from which the electrodes 20 extend) of the MRAM chip 11 is covered with the insulating material 13a-1 without substantially covering the electrodes 20. In other words, the insulating material 13a-1 is the thermal insulation area 13 of FIG. 1 between the MRAM chip 11 and the wiring substrate 19. The insulating material 13a-1 is preferably provided in sheet form with holes or apertures therethrough to receive the electrodes 20.

The insulating material 13a-1, is composed of low-density materials, resins with low thermal conductivity, inorganic materials with low thermal conductivity, etc. In addition, when the insulating material 13a-1 is a sheet form, it is desirable for the insulating material 13a-1 to have an opening part with a size of X equal to or larger than the width of the electrodes 20 in parts corresponding to the electrodes 20.

Moreover, when the insulating material 13a-1 is a sheet form, the insulating material 13a-1 may have a function as an anisotropic conductive film. In this case, as the anisotropic conductive film, ACF or ACP is used. Since the ACF or ACP is composed of a material containing conductive particles in an adhesive material called a binder, a material with a thermal conductivity of 0.3 W/mK or lower is used as the binder.

A metal cap 23 is mounted on the wiring substrate 19 to cover the upper surface and the side surfaces of the MRAM chip 11. The area enclosed with the wiring substrate 19 and the metal cap 23 functions as the thermal insulation area 13 of FIG. 1. In this area, an insulating material 13a-2 is filled. The insulating material 13a-2 is composed of gases or liquids with low thermal conductivity, etc.

On the second surface of the wiring substrate 19, the external terminals 22 of the package are arranged. The external terminals 22 of the package are connected to the external terminals 18 of the MRAM chip 11 via the conducting wires 21 in the wiring substrate 19. In this example, the external terminals 22 of the package are depicted with an image as conductive bumps (solder bumps), however instead of the conductive bumps, conductive pins (metal pillars) may also be adapted.

Here, in this example, part or the whole of the metal cap 23 may be covered with a molding material such as epoxy resin.

Therefore, according to the fourth embodiment, the whole of the MRAM chip is covered with the insulating materials 13a-1 and 13a-2 as the thermal insulation area 13 of FIG. 1. Therefore, in case this nonvolatile semiconductor memory device is placed in a high-temperature environment during the mounting process, the effect of magnetization direction reversal of the reference layer or memory layer of the magnetoresistive element due to the thermal fluctuation may be reduced.

### (Modified Example)

As a modified example of the first and the second embodiments, metal particles or magnetic particles having a magnetic shield effect may be included in the insulating materials 13a, 13a-1, and 13a-2. In addition, instead of these particles or along with these particles, metal particles or magnetic particles having a magnetic shield effect may also be included in the molding material 13b.

Moreover, as a modified example of the third and the fourth embodiments, metal particles or magnetic particles having a magnetic shield effect may be included in the insulating materials 13a-1, and 13a-2.

Therefore, an unintended magnetization reversal of the memory layer due to environmental conditions such as heat or an external magnetic field can be prevented by rendering an effect of protecting the magnetoresistive effect element from heat and a magnetic shield effect to the enclosure. Therefore, the reliability of a magnetic random access memory can be further improved.

### (Manufacturing Methods)

The methods for manufacturing the nonvolatile semiconductor memory devices of the first to the fourth embodiments will be explained.

The method for manufacturing the structure of the first embodiment (FIG. 2):

First, as shown in FIG. 6, for example, the MRAM chip 11 is fixed onto the die pad 14 of a Cu (copper)-lead frame by the conductive paste 15. Next, as shown in FIG. 7, the external electrodes (pads) 18 of the MRAM chip 11 and the lead frame are connected by the bonding wires 16.

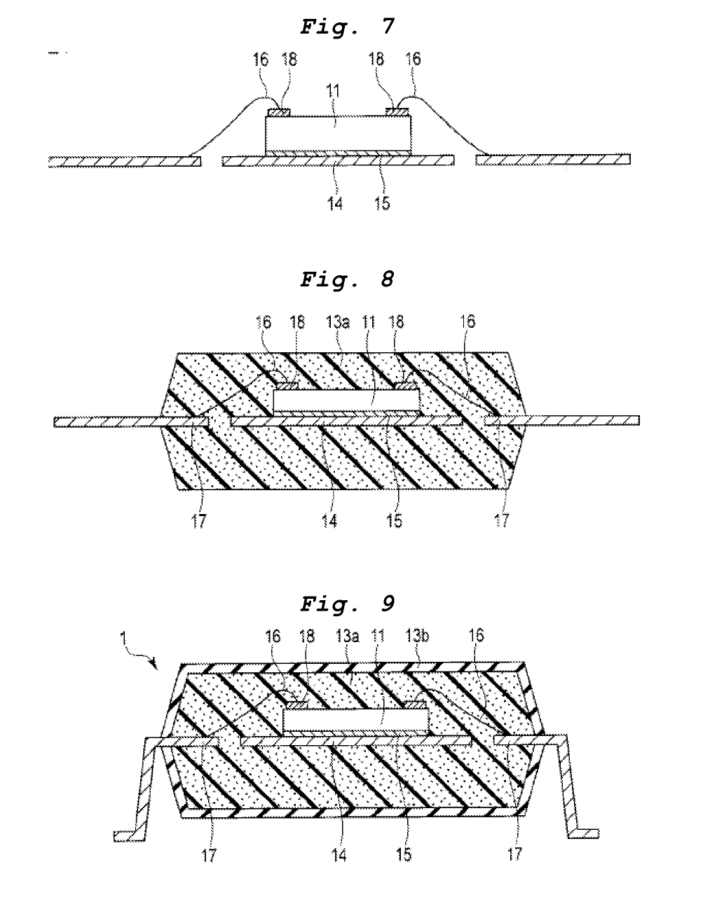

Next, as shown in FIG. 8, the MRAM chip 11 is covered with the insulating material (for example, foam plastic) 13a. This step can be carried out by a resin sealing technique using a mold.

Finally, as shown in FIG. 9, the molding material 13b for covering the insulating material 13a is formed. The molding material 13b can be formed by the resin sealing technique using a mold. In addition, a step where the molding material 13b is spread on the surface of the insulating material 13a may also be used.

Through the above processes, the nonvolatile semiconductor memory device 1 is completed.

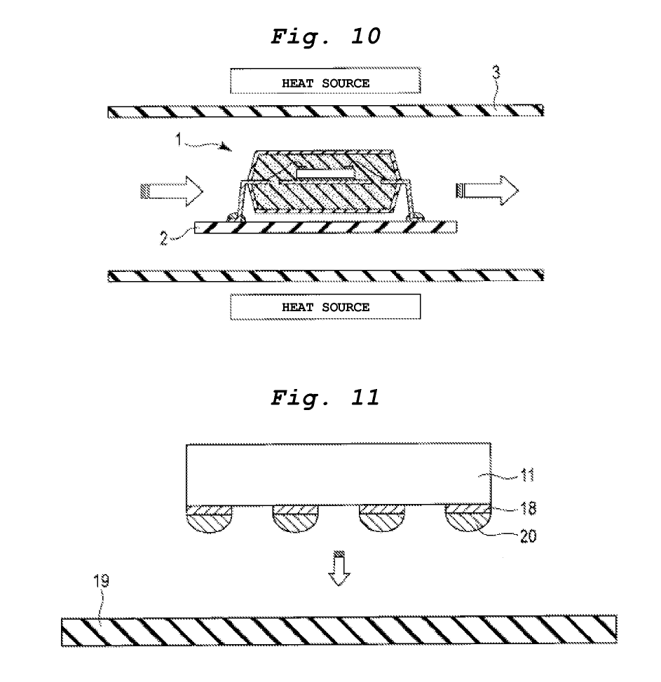

Next, for example, as shown in FIG. 10, the nonvolatile semiconductor memory device 1 is mounted on the wiring substrate (for example, printed-circuit board) 2 and arranged in the reflow furnace 3. Next, a solder is melted by a reflow process, and the nonvolatile semiconductor memory device 1 is fixed onto the wiring substrate 2. The thermal fluctuation due to the reflow process is reduced by the insulating material 13a.

The method for manufacturing the structure of the second embodiment (FIG. 3):

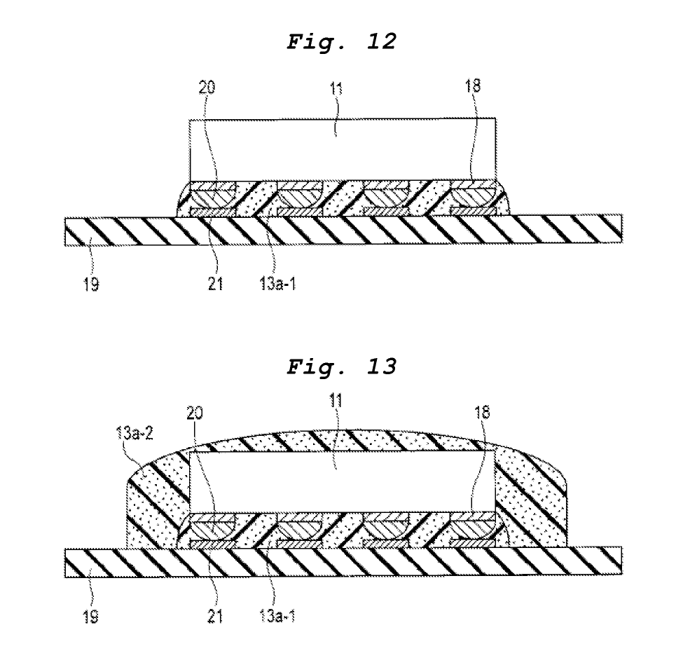

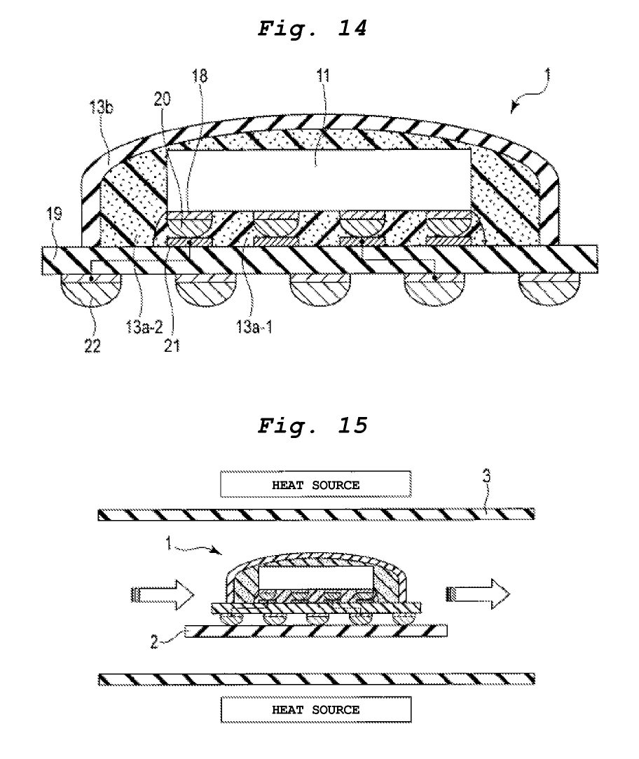

First, as shown in FIG. 11, the MRAM chip 11 is fixed onto the first surface of the wiring substrate 19 by a flip-chip connection. Next, as shown in FIG. 12, the insulating material (for example, foam plastic) 13a-1 is filled between the MRAM chip 11 and the wiring substrate 19. The insulating material 13a-1 is filled between the electrodes 20.

Next, as shown in FIG. 13, the insulating material (for example, foam plastic) 13a-2 for covering the upper surface and the side surface of the MRAM chip 11 is formed. The insulating material 13a-2 can be formed by dropping a material constituting the insulating material 13a-2 from the top of the MRAM chip 11 and the curing material.

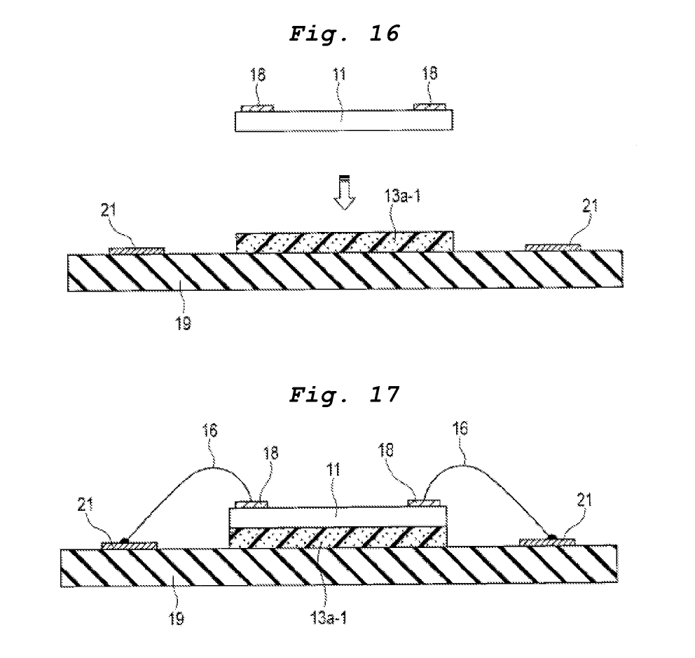

Finally, as shown in FIG. 14, a molding material 13b for covering the insulating material 13a-2 is formed. The molding material 13b can be formed by adapting a step where the molding material 13b is spread on the surface of the insulating material 13a-2.

In addition, the external terminals (for example, solder balls) 22 of the package are formed on the second surface of the wiring substrate 19.

Through the above processes, the nonvolatile semiconductor memory device 1 is completed.

Next, as shown in FIG. 15, the nonvolatile semiconductor memory device 1 is mounted on the wiring substrate (for example, printed-circuit board) 2 and arranged in the reflow furnace 3. Next, a solder is melted by the reflow process, and the nonvolatile semiconductor memory device 1 is fixed onto the wiring substrate 2. The thermal fluctuation due to the reflow process is reduced by the insulating materials 13a-1 and 13a-2.

The method for manufacturing the structure of the third embodiment (FIG. 4):

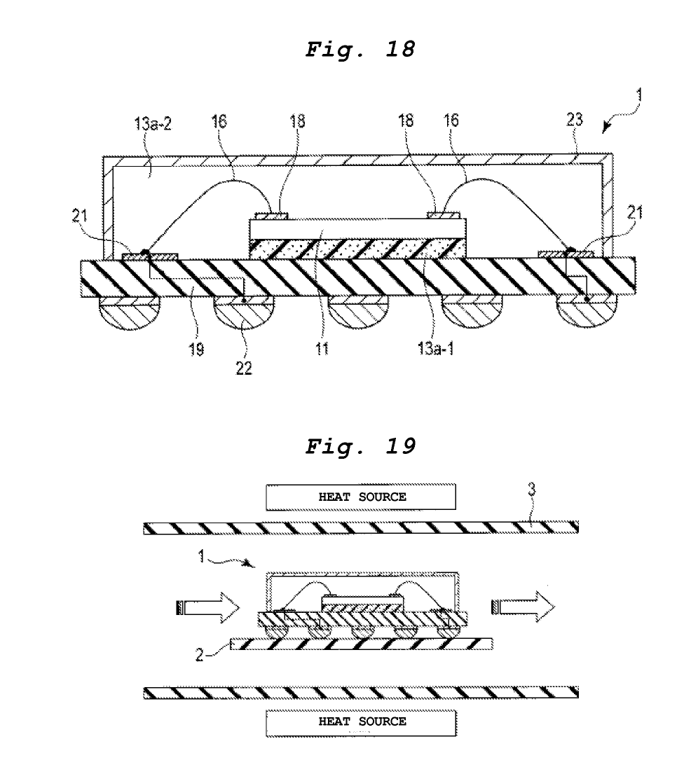

First, as shown in FIG. 16, the insulating material (for example, insulating sheet) 13a-1 is arranged on the first surface of the wiring substrate 19. In addition, the MRAM chip 11 is arranged on the insulating material 13a-1. Next, as shown in FIG. 17, the external electrodes (pads) 18 of the MRAM chip 11 and the conducting wires 21 on the first surface of the wiring substrate 19 are connected by the bonding wires 16.

Next, as shown in FIG. 18, the metal cap 23 is mounted on the first surface of the wiring substrate 19. At that time, the insulating material 13a-2 is filled in the area enclosed with the wiring substrate 19 and the metal cap 23. The insulating material 13a-2, for example, is an inert gas.

Here, the insulating material 13a-2 can be filled in the area enclosed with the wiring substrate 19 and the metal cap 23 at the same time of mounting of the metal cap 23 on the first surface of the wiring substrate 19 or can also be filled in the area enclosed with the wiring substrate 19 and the metal cap 23 after mounting of the metal cap 23 on the first surface of the wiring substrate 19.

However, in the latter example, an injection opening for injecting an inert gas as the insulating material 13a-2 is required to be installed in the metal cap 23. A method that seals the metal cap in an insulating insert gas may also be employed.

In addition, the external terminals (for example, solder balls) 22 of the package are formed on the second surface of the wiring substrate 19.

Through the above processes, the nonvolatile semiconductor memory device 1 is completed.

Next, as shown in FIG. 19, the nonvolatile semiconductor memory device 1 is mounted on the wiring substrate (for example, printed-circuit board) 2 and arranged in the reflow furnace 3. Next, the solder is melted by a reflow process, and the nonvolatile semiconductor memory device 1 is fixed onto the wiring substrate 2. The thermal fluctuation due to the reflow process is reduced by the insulating materials 13a-1 and 13a-2.

The method for manufacturing the structure of the fourth embodiment (FIG. 5):

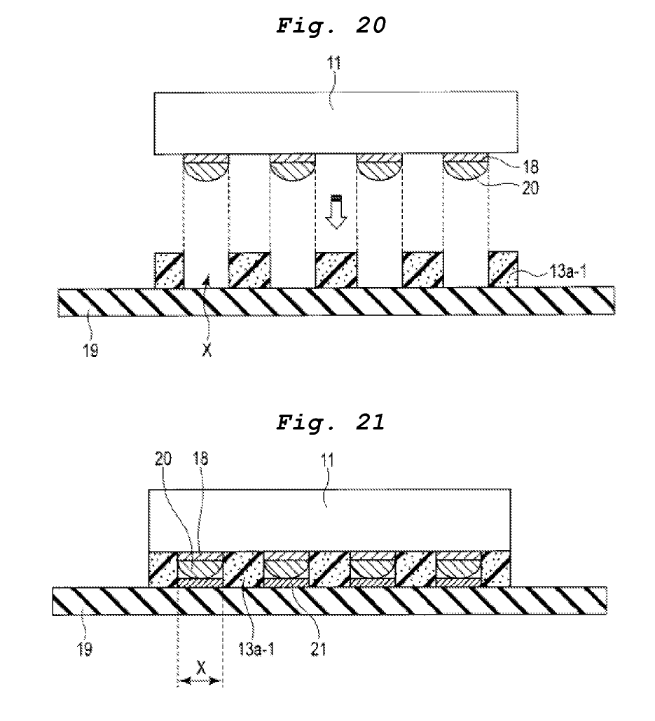

First, as shown in FIG. 20, the insulating material (for example, insulating sheet) 13a-1 is arranged on the first surface of the wiring substrate 19. The insulating material 13a-1 has openings at prescribed positions corresponding to electrodes 20 on the MRAM chip 11. In addition, the MRAM chip 11 is fixed onto the first surface of the wiring substrate 19 by a flip-chip connection. At that time, as shown in FIG. 21, the electrodes 20 of the MRAM chip 11 are connected to the conducting wires 21 on the first surface of the wiring substrate 19 via an opening part X of the insulating material 13a-1.

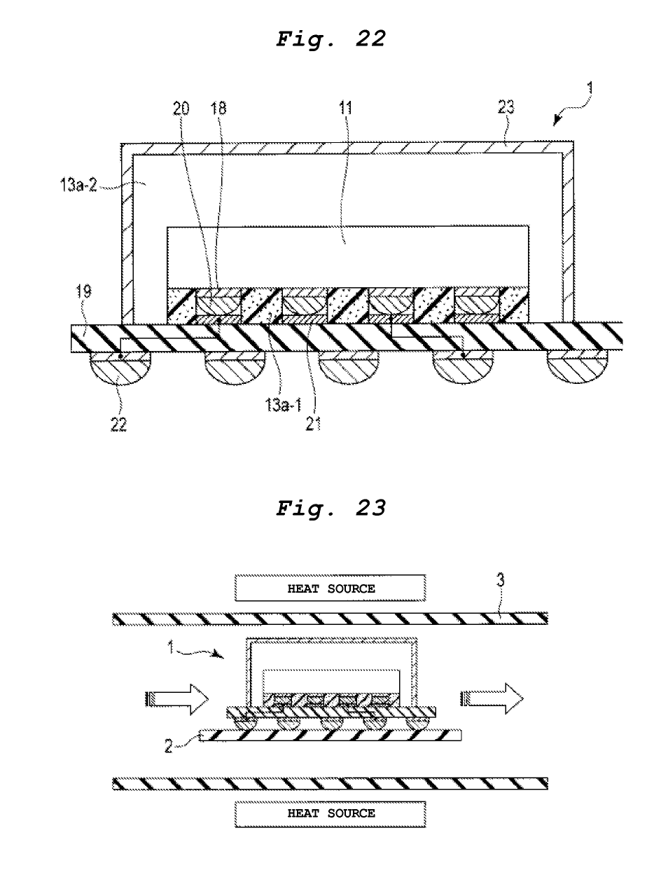

Next, as shown in FIG. 22, a metal cap 23 is mounted on the first surface of the wiring substrate 19. At that time, the insulating material 13a-2 is filled in the area enclosed with the wiring substrate 19 and the metal cap 23. The insulating material 13a-2, for example, is an inert gas.

Here, the insulating material 13a-2 can be filled in the area enclosed with the wiring substrate 19 and the metal cap 23 at the same time of mounting of the metal cap 23 on the first surface of the wiring substrate 19 or can also be filled in the area enclosed with the wiring substrate 19 and the metal cap 23 after mounting of the metal cap 23 on the first surface of the wiring substrate 19.

However, in the latter example, an injection opening for injecting an inert gas as the insulating material 13a-2 is required to be installed in the metal cap 23.

In addition, the external terminals (for example, solder balls) 22 of the package are formed on the second surface of the wiring substrate 19.

Through the above processes, the nonvolatile semiconductor memory device 1 is completed.

Next, for example, as shown in FIG. 23, the nonvolatile semiconductor memory device 1 is mounted on the wiring substrate (for example, printed-circuit board) 2 and arranged in the reflow furnace 3. Next, the solder is melted by a reflow process, and the nonvolatile semiconductor memory device 1 is fixed onto the wiring substrate 2. The thermal fluctuation due to the reflow process is reduced by the insulating materials 13a-1 and 13a-2.

### (Structural Example of Magnetic Random Access Memory)

A structural example of a magnetic random access memory in an MRAM chip will be explained.

In the following, a 1T1R type memory cell array in which one memory cell is provided with one magnetoresistive effect element 1 and one selective transistor will be explained as an example.

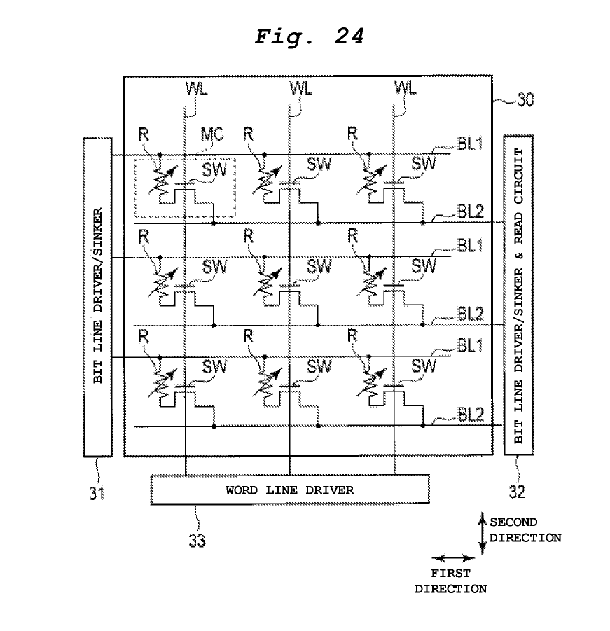

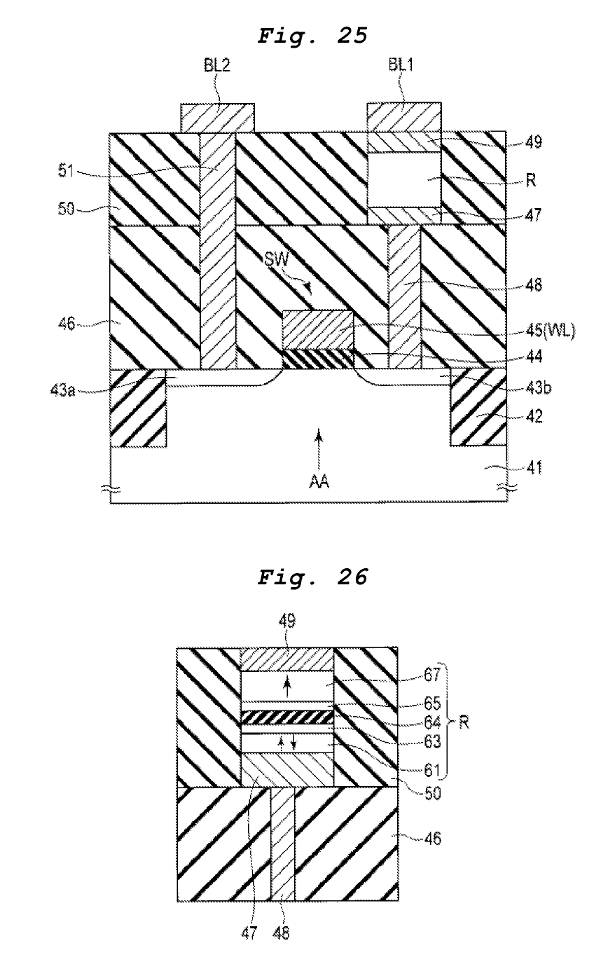

FIG. 24 shows an equivalent circuit of the 1T1R type memory cell array.

A memory cell array 30 is provided with several memory cells MC that are arranged in an array shape. At least one memory cell MC includes one magnetoresistive effect element R and one selective transistor (FET) SW.

The magnetoresistive effect element R and the selective transistor SW are connected in series, their one end is connected to a first bit line BL1, and the other end is connected to a second bit line BL2. A control terminal (gate terminal) of the selective transistor SW is connected to word lines WL.

The first bit line BL1 extends in a first direction, and the end thereof is connected to a bit line driver/sinker 31. The second bit line BL2 extends in the first direction, and the end thereof is connected to a bit line driver/sinker and a read circuit 32.

However, through modifications, the first bit line BL1 can be connected to the bit line driver/sinker and the read circuit 32, and the second bit line BL2 can be connected to the bit line driver/sinker 31.

In addition, the positions of the bit line driver/sinker 31 and the bit line driver/sinker and the read circuit 32 may be reversed, or both of them may also be arranged at the same position.

The word lines WL extend in a second direction, and the ends are connected to a word line driver 33.

FIG. 25 shows an example of the memory cells.

The selective transistor SW is disposed in or on an active area AA in the semiconductor substrate 41. The active area AA is enclosed with an element isolation insulating layer 42 in a semiconductor substrate 41. In this example, the element isolation insulating layer 42 has a Shallow Trench Isolation (STI) structure.

The selective transistor SW includes source/drain diffusion layers 43a and 43b in the semiconductor substrate 41, a gate insulating layer 44 on a channel between the diffusion layers, and a gate electrode 45 on the gate insulating layer 44. The gate electrode 45 functions as the word line WL.

An interlayer dielectric layer 46 covers the selective transistor SW. The upper surface of the interlayer dielectric layer 46 is generally flat, and a lower electrode 47 is disposed on the interlayer dielectric layer 46. The lower electrode 47 is connected to the source/drain diffusion layer 43b of the selective transistor SW via a contact plug 48 extending through the interlayer dielectric layer 46 to diffusion layer 43b.

A magnetoresistive effect element R is disposed on the lower electrode 47. In addition, an upper electrode 49 is disposed on the magnetoresistive effect element R. The upper electrode 49, functions as a hard mask layer when the magnetoresistive effect element R is formed.

An interlayer dielectric layer 50 is disposed on the interlayer dielectric layer 46 and encircles the magnetoresistive effect element R. The upper surface of the interlayer dielectric layer 50 is generally flat, and the first and second bit lines BL1 and BL2 are arranged on the interlayer dielectric layer 50. The first bit line BL1 is connected to the upper electrode 49. The second bit line BL2 is connected to the source/drain diffusion layer 43a of the selective transistor SW via a contact plug 51.

FIG. 26 shows a first example of the magnetoresistive effect element.

In the figure, the same symbols are given to the same elements as the elements shown in FIG. 25.

The magnetoresistive effect element R is a top pin type.

A memory layer (ferromagnetic layer) 61 whose magnetizing direction is variable is disposed on the lower electrode 47.

The memory layer 61 is composed of a vertical magnetizing film. The vertical magnetizing film, has an artificial lattice in which an element, which is selected from Fe, Co, and Ni, and an element, which is selected from Cr, Pt, Pd, Ir, Rh, Ru, Os, Re, and Au, or alloys are thereof layered. For example, a structure in which Co and Pt are layered in an alternate fashion, a structure in which Co and Pd are layered in an alternate fashion, and a structure in which Co and Ru are layered in an alternate fashion to constitute the vertical magnetic film.

In addition, this vertical magnetizing film can adjust the magnetization characteristics by composition ratio, ratio of a magnetic material and a nonmagnetic material, etc. Moreover, the vertical magnetizing film can also be constructed by combining Ru and an antiferromagnetic material (for example, PtMn, IrMn, etc.).

The lower electrode 47 is composed of a material for controlling the crystal orientation of the memory layer 61. For example, the lower electrode 47 is preferably Pt, Ir, Ru, Cu, etc.

A diffusion barrier layer (not shown) is disposed on the memory layer 61, and an interfacial magnetic layer 63 is disposed on the diffusion barrier layer 62. A tunnel barrier layer 64 is disposed on the interfacial magnetic layer 63. In addition, an interfacial magnetic layer 65 is disposed on the tunnel barrier layer 64, and a diffusion barrier layer (not shown) is disposed on the interfacial magnetic layer 65. A reference layer (ferromagnetic layer) 67 whose magnetizing direction is set is disposed on the diffusion preventing layer.

The tunnel barrier layer 64, for example, is composed of MgO, CaO, SrO, TiO, VO, NbO, Al₂O₃, etc., and is preferably an oxide having an NaCl structure.

If the tunnel barrier layer 64 is formed on an alloy mainly composed of Fe, Co, and Ni, amorphous CoFeB, a crystal structure oriented to (100) plane can be obtained therein. In other words, the interfacial magnetic layer 63 is preferably amorphous CoFeB.

The reference layer 67, for example, is composed of an L1o system regular alloy such as FePd and FePt. In addition, if an element such as Cu is added to the L1o system regular alloy, the saturation magnetization and the anisotropic magnetic energy density of the reference layer 67 can be adjusted.

The interfacial magnetic layers 63 and 65 are layers required for obtaining a high tunnel magnetoresistive effect (Tunneling Magneto-Resistance (TMR)). The interfacial magnetic layers 63 and 65 are installed to improve the matching property of the memory layer 61 and the tunnel barrier layer (for example, an oxide having an NaCl structure oriented to (100) plane) 64 and the matching property of the tunnel barrier layer 64 and the reference layer 67.

Therefore, the interfacial magnetic layers 63 and 65 are preferably composed of materials with a small lattice mismatch with the tunnel barrier layer 64. Since the amorphous CoFeB is a material with a small lattice mismatch with the tunnel barrier layer 64, this material is desirable for obtaining a high TMR effect.

The upper electrode (cap layer) 49 is composed of a material such as Ru and Ta functioning as a hard mask when the magnetoresistive effect element R is patterned or formed.

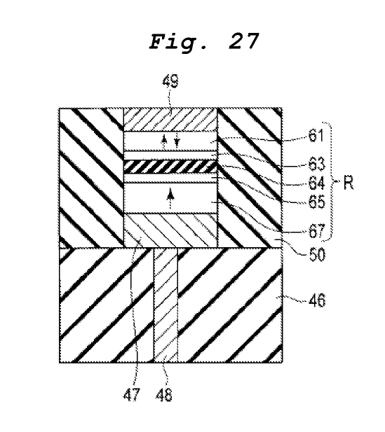

FIG. 27 shows a second example of the magnetoresistive effect element.

In the figure, the same symbols are given to the same elements as the elements shown in FIG. 25.

The magnetoresistive effect element R is a bottom pin type.

The reference layer (ferromagnetic layer) 67 whose magnetizing direction is set is disposed on the lower electrode 47. The diffusion preventing layer 66 is disposed on the reference layer 67, and the interfacial magnetic layer 65 is disposed on the diffusion preventing layer (Not shown) The tunnel barrier layer 64 is disposed on the interfacial magnetic layer 65. In addition, the interfacial magnetic layer 63 is disposed on the tunnel barrier layer 64, and the diffusion preventing layer (not shown) is disposed on the interfacial magnetic layer 63. The memory layer (ferromagnetic layer) 61 whose magnetizing direction is variable is disposed on the diffusion preventing layer 62.

The memory layer 61 and the reference layer 67 are composed of a vertical magnetizing film. Since the material examples of the memory layer 61 and the reference layer 67 have been explained in the first example (FIG. 26), their explanation is omitted herein.

In addition, since the material examples of the lower electrode 47, the diffusion preventing layer 62, the interfacial magnetic layer 63, the tunnel barrier layer 64, the interfacial magnetic layer 65, the diffusion preventing layer 66, and upper electrode 49 have also been explained in the first example (FIG. 26), their explanation is omitted herein.

Here, the magnetoresistive effect element R is not limited to the first and second examples but can be variously modified.

Moreover, in manufacturing the magnetoresistive effect element R, a well-known cumulative techniques and etching techniques can be employed. However, when the magnetoresistive effect element R is patterned, Ion beam etching (IBE), Reactive ion etching (RIE), or Gas cluster Ion beam etching (GCIB) are employed. Furthermore, it is known that when the magnetoresistive effect element R is patterned by these methods, a residue as a reattachment layer (Re-deposition layer) is formed on the side wall of the magnetoresistive effect element R. For this reason, it is necessary to insulate the residue or to optimize a taper angle (an angle between the film surface of each layer in the layered structure and the side surface) of the magnetoresistive effect element R and working conditions (the kind of gas, etc.) so that no residue is generated.

In addition, for this reason, a method that separately patterns both of them while making the size of the memory layer 61 and the size of the reference layer 67 different is also effective.

### (Others)

This embodiment has been explained on the nonvolatile semiconductor memory device provided with the MRAM chip, however the basic concept can also be applied to other semiconductor chips (for example, CMOS sensor, MEMS sensor, temperature/pressure sensor, etc.) in which the thermal fluctuation causes a problem.

### CONCLUSION

According to these embodiments, the reduction of a write current and the improvement of thermal stability can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile memory device comprising:
a memory element;
a substrate;
a connecting element for adhering the memory element to the substrate;
a covering extending over the memory element and at least a portion of said substrate and forming a volume therein; and
a thermal insulating element located within the volume and extending over at least one surface of the memory element

2. The non-volatile memory device of claim 1, wherein
the memory element has a magnetic tunnel junction structure.

3. The non-volatile memory device of claim 1, wherein
Said thermal insulating element has a thermal conductivity of less than 0.3 W/mK.

4. The non-volatile memory device of claim 1, wherein
the thermal insulating element includes:
a fluid; and
a solid insulating element located within the volume formed between the substrate and the coverings.

5. The non-volatile memory of claim 1, wherein
the memory element includes at least one electrode projecting there from contacting the substrate; and
the thermal insulating element is located between the memory element and the substrate in a regions surrounding the electrode.

6. The non-volatile memory of claim 1, wherein
the covering is a resin.

7. The non-volatile memory of claim 1, wherein
the thermal insulating element is a gas located between the covering and the memory element.

8. A method of forming a packaged non-volatile memory, comprising:
providing a non-volatile memory element;
positioning the non-volatile memory element on a substrate and adhering the memory element to the substrate;
providing a thermal isolation material adjacent to at least or surface of the memory element; and
enclosing the memory element, substrate and thermal insulation element in a covering.

9. The method of claim 8, further including the steps of:
interposing a first thermal isolation element between at least a portion of the memory element and the substrate, and;
interposing a second thermal isolation element between the memory element and the covering.

10. The method of claim 9, wherein the first thermal isolation element is a solid and the second isolation element is a gas.

11. The memory device of claim 9, where the memory element is formed on a flip-chip.

12. The method of claim 8, further including the steps of:
forming an encapsulant over the thermal insulation element and memory element.

13. The method of claim 12, wherein the encapsulant forms the covering.

14. The memory device of claim 8, wherein the memory element is a magnetic tunnel junction.

15. The memory device of claim 8, wherein the substrate is a lead frame.

16. A nonvolatile semiconductor memory device, comprising:
an MRAM chip including a magnetoresistive effect element having a reference layer whose magnetizing direction is set, a memory layer whose magnetizing direction is variable, and a nonmagnetic layer between the layers; and
an enclosure having a thermal insulation area overlaying the MRAM chip and a molding material for covering a thermal insulation area, wherein
the thermal insulation area includes a first area for covering the lower surface of the MRAM chip and a second area for covering the upper surface of the MRAM chip; and
the first and second areas have materials different from each other.

17. The nonvolatile semiconductor memory device according to claim 16, wherein
the thermal insulation area has a thermal conductivity of 0.3 W/mK or lower.

18. The nonvolatile semiconductor memory device according to claim 16, wherein
the thermal insulation area includes metal particles or magnetic particles.

19. The nonvolatile semiconductor memory device according to claim 18, wherein
the enclosure further comprises a molding material overlaying the thermal insulation are, and
the molding material includes metal particles or magnetic particles.
